(19) United States
(12) Patent Application Publication
(10) Pub. No.: US 2006/0186544 A1
(43) Pub. Date: Aug. 24, 2006

(54) Copper bonding wire for semiconductor packaging

(75) Inventors: Sung-Joon Won, Yongin-city (KR); Oh Min Kwon, Hanam-city (KR); Sung Mun Lee, Seoul (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: MK ELECTRON CO., LTD., Yongin-city (KR)

(21) Appl. No.: 11/252,646

(22) Filed: Oct. 18, 2005

(30) Foreign Application Priority Data
Feb. 18, 2005 (KR) 10-2005-0013511

(51) Int. Cl. H01L 23/48

(52) U.S. Cl. 257/741

(57) ABSTRACT

Provided is a copper bonding wire formed of a high purity copper of 99.999% or more including at least one of P and Nb within a range between 20 wt ppm and 100 wt ppm and at least one of Zr, Sn, Be, Nd, Sc, Ga, Fr, and Ra within a range between 1 wt ppm and 100 wt ppm. Here, a total content of the added elements is restricted within a range between 20 wt ppm and 200 wt ppm, and a residual amount of the copper bonding wire is a high purity copper of 99.98% or more. As a result, metal squeeze out and chip cratering can be reduced in a general semiconductor chip and a low dielectric semiconductor chip. Also, a short tail of the copper bonding wire occurring during bonding of the copper bonding wire to a lead finger can be reduced.

### CROSS-REFERENCE TO RELATED PATENT APPLICATION

This application claims the benefit of Korean Patent Application No. 10-2005-0013511, filed on Feb. 18, 2005, in the Korean Intellectual Property Office, the disclosure of which is incorporated herein in its entirety by reference.

### BACKGROUND OF THE INVENTION

1. Field of the Invention

The present invention relates to a copper bonding wire for semiconductor packaging, and more particularly, to a copper bonding wire easily applied to a package using a lead frame of parts used as external connectors.

2. Description of the Related Art

Referring to FIG. 1, a semiconductor package 100 includes a semiconductor chip 10 and a lead part of a lead frame, i.e., a lead finger 50. The semiconductor chip 10 is formed of an integrated circuit (IC) using a non-conductor such as silicon (Si) or germanium (Ge) as a thin substrate. The lead finger 50 is connected to the semiconductor chip 10 via a bonding wire 30 to directly input and/or output various types of electric signals to an external circuit. A portion through which the semiconductor chip 10 is connected to the bonding wire 30 is formed in a compression ball 20.

As shown in FIG. 2, an end of the bonding wire 30 coming out of a capillary 70 is melted using an electro flame off (EFO) 60 to form a ball 90 having a predetermined size. The ball 90 is bonded to the semiconductor chip 10 to form the compression ball 20, the capillary 70 is moved to move the bonding wire 30 to the lead finger 50 so as to bond the bonding wire 30 to the lead finger 50, and the bonding wire 30 is cut. As a result, wiring is completed.

A general bonding wire is formed of a gold (Au) alloy having good heat-resisting and mechanical properties and being easily manufactured. However, Au is high-priced and does not satisfy requirements of power IC devices and ultrahigh speed IC packages having recently been developed in terms of electrical property.

Since copper (Cu) has a low electric resistance and a low noise occurrence rate, Cu is a conductor of an electronic circuit the most suitable for transmitting a signal. Also, Cu has a good softness and thus can be easily manufactured as a fine wire of a bonding wire type used for a semiconductor. Also, Cu has better heat-resisting, mechanical, manufacturing, and electrical properties than Au and thus is suitable as a material for bonding wire. Cu is very cheap and economical. In spite of these advantages, Cu has a poorer oxidation resistance than Au and is harder than Au. Thus, it is difficult for Cu to replace Au in terms of bonding wire.

In particular, as shown in FIG. 3, a Cu bonding wire causes a metal squeeze out in which a surface layer of the semiconductor chip 10 is squeezed out around the compression ball 20 by the compression ball 20 to expose a bottom layer of the semiconductor chip 10 so as to cause poor bonding of the semiconductor chip 10 to the bonding wire 30. As shown in FIG. 4, chip cratering occurs. In other words, a crack 80 is formed in the semiconductor chip 10 to crater the semiconductor chip 10 so that the semiconductor chip 10 is boned to the compression ball 20 and then broken down. Thus, an electric signal is not transmitted or a boding strength of the bonding wire 30 is low. As a result, the bonding wire 30 comes easily apart from the semiconductor chip 10 or comes apart with the semiconductor chip 10 that is broken down.

Also, a length of the bonding wire 30 necessary for a continuous bonding work is secured to pull the bonding wire 30 during bonding to the lead finger 50 so as to break the bonding wire 30 from a bonding portion between the bonding wire 30 and the lead finger 50. However, the bonding wire 30 is early broken down because of a reaction of the lead finger 50 caused by a strong force put by a high hardness of the bonding wire 30. Thus, only a bonding wire 85 having a shorter length than a length necessary for a next bonding work is left. As a result, a short tail phenomenon occurs as shown in FIG. 5. The short tail phenomenon lowers the productivity of semiconductor packages together with metal squeeze out and chip cratering.

For an increase in a heat-resistance of a bonding wire and a low hardness of the bonding wire, there have been suggested Korean Patent Publication No. 1987-0005447, entitled “Bonding Wire for Semiconductor Device and Method of Fabricating the Same,” European Patent No. 0283587, entitled “Bonding Wire,” Japanese Patent Publication No. 62-078861, entitled “Copper Wire for Bonding of Semiconductor Element,” Japanese Patent Publication No. 62-080241, entitled “Copper Wire for Bonding Semiconductor Device”, Japanese Patent Publication No. 61-099646, entitled “Copper Wire for Bonding of Semiconductor Device,” and the like. However, these patents focus on chip cratering and a crack occurring at a ball neck between a ball and a bonding wire during forming of a loop after ball bonding and have limitations in solving a short tail of a lead finger and metal squeeze out of a semiconductor chip.

Besides the above-described techniques, conventional techniques for copper bonding wires have been developed to prevent chip breaking, chip cratering, and the like. The conventional techniques are applied only to existing hard chips not to semiconductor chips using a low dielectric (low-k) material, the semiconductor chips having been recently developed and gradually widely applied. Thus, chip breaking, chip cratering, metal squeeze out, and the like are quite serious.

A low-k semiconductor chip in which an application of a conventional copper bonding wire is problematic will now be described.

A number of wires of a semiconductor chip has been continuously increased to increase a speed of a semiconductor package. A wire must be formed of a thinner metal line due to a reduction in a size of a pad part of a surface of a chip to which a bonding wire is bonded and a reduction in a gap between wires to increase the number of wires. However, a transmission of an electric signal is poor due to noise generated by a reduction in a thickness of a wire metal and the reduction in the gap between the wires. In the low-k semiconductor chip, to improve the poor transmission of the electric signal, the wire is coated with a thin film so as to be insulated. As a result, the wire has a lower dielectric constant k than currently used SiO₂. If the dielectric constant k is lowered, capacitance of the wire is reduced and an insulating characteristic of the wire is increased. In the case of SiO₂ used as a material for an existing wire, a dielectric constant is within a range between 3.9 and 4.5, and a fluorosilicate glass has a dielectric constant within a range between 3.2 and 4.0. However, a dielectric constant of a material used for low-k semiconductor chips recently developed is 3.0 or less.

The use of such a low-k material causes problems. In other words, existing materials having very low dielectric constants are soft and very weak. Thus, bonding strengths of the existing materials to silicon or metal wires are weak. As a result, the existing materials are easily creviced or taken off even by weak forces transmitted from external sources. Accordingly, a semiconductor chip may be cratered or broken down by a strength for bonding a bonding wire to a low-k semiconductor chip. Thus, a copper bonding wire developed according to a conventional technique cannot be easily applied to the semiconductor chip.

Besides, these problems, there has not been developed a technique for a copper bonding wire preventing or reducing short tail of a lead finger greatly affecting a work important in a semiconductor fabricating process.

### SUMMARY OF THE INVENTION

The present invention provides a copper bonding wire for semiconductor packaging for improving a metal squeeze out of a chip pad, chip cratering, and a short tail of the bonding wire.

According to an aspect of the present invention, there is provided a copper bonding wire formed of a high purity copper of 99.999% or more including at least one of P and Nb within a range between 20 wt ppm and 100 wt ppm and at least one of Zr, Sn, Be, Nd, Sc, Ga, Fr, and Ra within a range between 1 wt ppm and 100 wt ppm. Here, a total content of the added elements is restricted within a range between 20 wt ppm and 200 wt ppm, and a residual amount of the copper bonding wire is a high purity copper of 99.98% or more.

According to another aspect of the present invention, there is provided a copper bonding wire formed of a high purity copper of 99.999% or more including at least one of P and Nb within a range between 20 wt ppm and 100 wt ppm and at least one of Cs, Lu, Ta, Re, Os, Ir, Po, At, Pr, Pm, Sm, and Gd within a range 1 wt ppm and 50 wt ppm. Here, a total content of the added elements is restricted within a range between 20 wt ppm and 150 wt ppm, and a residual amount of the copper bonding wire is a high purity copper of 99.98% or more.

According to still another aspect of the present invention, there is provided a copper bonding wire formed of a high purity copper of 99.999% or more including at least one of P and Nb within a range between 20 wt ppm and 100 wt ppm, at least one of Zr, Sn, Be, Nd, Sc, Ga, Fr, and Ra within a range between 1 wt ppm and 100 wt ppm, and at least one of Cs, Lu, Ta, Re, Os, Ir, Po, At, Pr, Pm, Sm, and Gd within a range between 1 wt ppm and 50 wt ppm. Here, a total content of the added elements is restricted within a range between 20 wt ppm and 250 wt ppm, and a residual amount of the copper bonding wire is a high purity copper of 99.98% or more.

### BRIEF DESCRIPTION OF THE DRAWINGS

FIG. 1 is a view illustrating a connection state of a copper bonding wire of a general semiconductor package.

FIG. 2 is an enlarged view illustrating a discharge state for bonding a copper bonding wire to a semiconductor chip.

FIG. 3 is an enlarged view illustrating a metal squeeze out caused by a conventional copper bonding wire.

FIG. 4 is an enlarged view illustrating chip cratering caused by a conventional copper bonding wire.

FIG. 5 is an enlarged view illustrating a short tail caused by a conventional copper bonding wire.

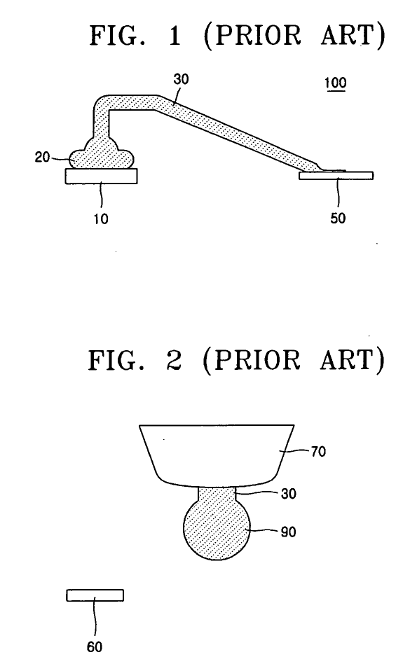

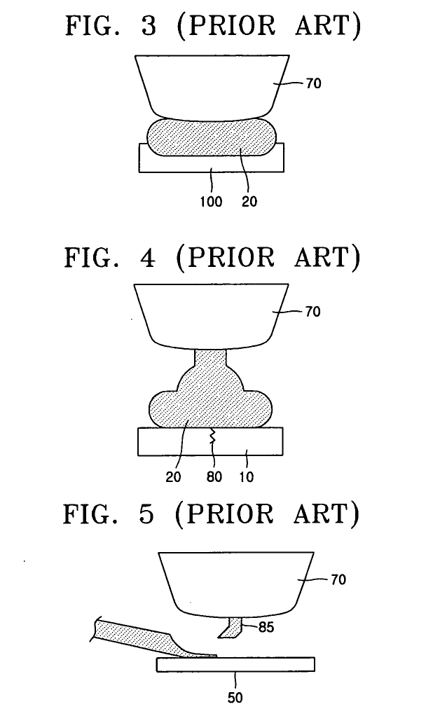

### DETAILED DESCRIPTION OF THE INVENTION

Hereinafter, a copper bonding wire according to the present invention will be described in detail.

A copper bonding wire according to the present invention may be mainly formed of a high purity oxygen free copper including a small amount of impurities and not including oxygen. The high purity oxygen free copper is mixed with another element in the unit of wt ppm within a range keeping a high electric conductivity state of the high purity oxygen free copper to lower a hardness of the high purity oxygen free copper. Next, the high purity oxygen free copper is manufactured as a bonding wire. Thus, metal squeeze out, chip cratering, and a short tail occurring during bonding of the bonding wire to a semiconductor package can be prevented. A content of the high purity oxygen free copper may be adjusted so that the copper bonding wire is as hard as a gold bonding wire. However, a total content of an added element is adjusted so that a residual amount of the copper bonding wire is a copper having a high purity of 99.98% or more.

The copper bonding wire according to the present invention uses a copper having a high purity of 99.999% or more, at least one of P and Nb being added to the copper within a range between 20 wt ppm and 100 wt ppm. In a case where at least one of P and Nb is added to the high purity copper within the range between 20 wt ppm and 100 wt ppm, minute amounts of inevitable impurities O and S as deoxidization and desulfurization components contained in the high purity copper during forming of a ball of the copper bonding wire can be removed or a reaction of O around the high purity copper with the high purity copper can be prevented.

A copper bonding wire according to an embodiment of the present invention is formed by adding at least one of Zr, Sn, Be, Nd, Sc, Ga, Fr, and Ra within a range between 1 wt ppm and 100 wt ppm to a high purity copper of 99.999% including at least one of P and Nb within a range between 20 wt ppm and 100 wt ppm. A total content of at least one of P and Nb and at least one of Zr, Sn, Be, Nd, Sc, Ga, Fr, and Ra is restricted within a range between 20 wt ppm and 200 wt ppm. The restriction is imposed on the total content because of the following reason. If the total content is lower than the range between 20 wt ppm and 200 wt ppm, an addition effect does not show. If the total content is higher than the range between 20 wt ppm and 200 wt ppm, a high electric conductivity of the high purity copper is deteriorated.

If at least one of Zr, Sn, Be, Nd, Sc, Ga, Fr, and Ra is added, an ambient temperature tensile strength of the copper bonding wire becomes lower and a softness of the copper bonding wire is increased. Thus, the metal squeeze out occurring during bonding of the ball is reduced. An addition effect does not show in a case of an addition of 1 wt ppm or less. In a case of an addition exceeding 100 wt ppm, an amount of a non-reactive element remaining not evaporating during forming of the ball is increased. Thus, the hardness of the ball is increased. As a result, an addition amount of at least one of Zr, Sn, Be, Nd, Sc, Ga, Fr, and Ra is restricted within a range between 1 wt ppm and 100 wt ppm. A residual amount of the copper bonding wire is the copper having the high purity of 99.98% or more.

A copper bonding wire according to another embodiment is formed by adding at least one of Cs, Lu, Ta, Re, Os, Ir, Po, At, Pr, Pm, Sm, and Gd within a range between 1 wt ppm and 50 wt ppm to a high purity copper of 99.999% or more including at least one of P and Nb within a range 20 wt ppm and 100 wt ppm. A total content of the added elements is restricted within a range between 20 wt ppm 150 wt ppm. The restriction is imposed on the total content because of the following reason. If the total content is lower than the range between 20 wt ppm 150 wt ppm, an addition effect does not show. If the total content is higher than the range between 20 wt ppm and 150 wt ppm, a high electric conductivity of the high purity copper is deteriorated.

If at least one of Cs, Lu, Ta, Re, Os, Ir, Po, At, Pr, Pm, Sm, and Gd is added, a hardness of the copper bonding wire is lowered. Thus, occurrences of chip cratering and a short tail are reduced. An addition effect does not show in a case of an addition of 1 wt ppm or less. In a case of an addition exceeding 50 wt ppm, an amount of a non-reactive element remaining not evaporating during forming of the ball is increased. Thus, a hardness of a ball is increased. As a result, an addition amount of at least one of Cs, Lu, Ta, Re, Os, Ir, Po, At, Pr, Pm, Sm, and Gd is restricted within the range between 1 wt ppm and 50 wt ppm. A residual amount of the copper bonding wire is a high purity copper of 99.98% or more.

A copper bonding wire according to still another embodiment of the present invention is formed by adding at least one of Zr, Sn, Be, Nd, Sc, Ga, Fr, and Ra within a range between 1 wt ppm and 100 wt ppm and at least one of Cs, Lu, Ta, Re, Os, Ir, Po, At, Pr, Pm, Sm, and Gd within a range between 1 wt ppm and 50 wt ppm to a high purity copper of 99.999% or more including at least one of P and Nb within a range between 20 wt ppm and 100 wt ppm. A total content of the added elements is restricted within a range between 20 wt ppm and 250 wt ppm. The restriction is imposed on the total content because of the following reason. If the total content is lower than the range between 20 wt ppm and 250 wt ppm, an addition effect does not show. If the total content is higher than the range between 20 wt ppm and 250 wt ppm, a high electric conductivity of a copper is deteriorated.

If at least one of Zr, Sn, Be, Nd, Sc, Ga, Fr, and Ra and at least one of Cs, Lu, Ta, Re, Os, Ir, Po, At, Pr, Pm, Sm, and Gd are added, a hardness of the copper bonding wire is reduced and an ambient temperature elongation ratio of the copper bonding wire is increased. Thus, an occurrence of a short tail is reduced. Also, an oxide layer can be prevented from being formed on a surface of a ball during forming of the ball. In addition, S remaining in the copper bonding wire is evaporated so as to maximize a softness of the ball. As a result, occurrences of metal squeeze out and chip cratering are reduced. If the total content of the added elements is less than 20 wt ppm, an addition effect does not show. If the total content of the added elements exceeds 250 wt ppm, the hardness of the copper bonding wire is more increased than the softness of the copper bonding wire. Thus, the occurrences of metal squeeze out, chip cratering, and the short tail are increased. As a result, the total content must be restricted within the range between 20 wt ppm and 250 wt ppm.

Results of an experiment performed with respect to a copper alloy bonding wire with varying weight mixture ratios of added elements will now be described in detail.

A copper refined so as to have a purity of 99.98% or more was mixed with added elements in the unit of wt ppm as shown in Table 1, melted, forged, drawn to a wire having a diameter of 50 um, and thermally treated to improve a mechanical characteristic.

TABLE 1

| | | Content (wt ppm) of Added Elements of Copper Bonding Wire | | | | | | | | | | | | | | | | | | | | |
|---|---|---|---|---|---|---|---|---|---|---|---|---|---|---|---|---|---|---|---|---|---|---|
| Classification | | P | Nb | Zr | Sn | Nd | Sc | Ga | Fr | Ra | Cs | Lu | Ta | Re | Os | Ir | Po | At | Pr | Pm | Sm | Gd |
| Present | 1 | 150 | — | — | — | — | — | — | — | — | — | — | — | — | — | — | — | — | — | — | — | — |
| Invention | 2 | 150 | 10 | — | — | — | — | — | — | — | — | — | — | — | — | — | — | — | — | — | — | — |
| | 3 | 100 | — | — | — | — | — | — | — | — | — | — | — | — | — | — | — | — | — | — | — | — |
| | 4 | 100 | 10 | — | — | — | — | — | — | — | — | — | — | — | — | — | — | — | — | — | — | — |
| | 5 | 50 | — | — | — | — | — | — | — | — | — | — | — | — | — | — | — | — | — | — | — | — |
| | 6 | 50 | 50 | — | — | — | — | — | — | — | — | — | — | — | — | — | — | — | — | — | — | — |
| | 7 | 20 | — | — | — | — | — | — | — | — | — | — | — | — | — | — | — | — | — | — | — | — |
| | 8 | 20 | 50 | — | — | — | — | — | — | — | — | — | — | — | — | — | — | — | — | — | — | — |
| | 9 | 10 | — | — | — | — | — | — | — | — | — | — | — | — | — | — | — | — | — | — | — | — |
| | 10 | 10 | 10 | — | — | — | — | — | — | — | — | — | — | — | — | — | — | — | — | — | — | — |
| | 11 | — | 150 | — | — | — | — | — | — | — | — | — | — | — | — | — | — | — | — | — | — | — |
| | 12 | 10 | 150 | — | — | — | — | — | — | — | — | — | — | — | — | — | — | — | — | — | — | — |
| | 13 | — | 100 | — | — | — | — | — | — | — | — | — | — | — | — | — | — | — | — | — | — | — |
| | 14 | 10 | 100 | — | — | — | — | — | — | — | — | — | — | — | — | — | — | — | — | — | — | — |
| | 15 | — | 50 | — | — | — | — | — | — | — | — | — | — | — | — | — | — | — | — | — | — | — |
| | 16 | 50 | 50 | — | — | — | — | — | — | — | — | — | — | — | — | — | — | — | — | — | — | — |
| | 17 | — | 20 | — | — | — | — | — | — | — | — | — | — | — | — | — | — | — | — | — | — | — |
| | 18 | 50 | 20 | — | — | — | — | — | — | — | — | — | — | — | — | — | — | — | — | — | — | — |
| | 19 | — | 10 | — | — | — | — | — | — | — | — | — | — | — | — | — | — | — | — | — | — | — |
| | 20 | 10 | 10 | — | — | — | — | — | — | — | — | — | — | — | — | — | — | — | — | — | — | — |
| | 21 | 10 | 10 | 100 | 100 | — | — | — | — | — | — | — | — | — | — | — | — | — | — | — | — | — |
| | 22 | 50 | 50 | 100 | 100 | — | — | — | — | — | 50 | — | — | — | — | — | — | — | — | — | 10 | — |
| | 23 | — | — | 100 | — | — | — | — | — | — | — | — | — | — | — | — | — | — | — | — | — | — |
| | 24 | — | 50 | 100 | — | — | — | — | — | — | — | — | 50 | — | — | — | — | — | — | — | — | — |
| | 25 | 50 | — | 100 | — | — | — | — | — | — | — | — | — | — | — | 10 | — | — | 10 | — | — | — |
| | 26 | — | — | 50 | — | — | — | 50 | — | — | — | — | 10 | — | — | — | — | — | — | — | — | 25 |
| | 27 | — | — | — | 10 | — | 10 | 10 | — | — | — | — | 50 | — | — | — | — | — | — | — | — | — |
| | 28 | 10 | 10 | 20 | — | 20 | — | — | 50 | — | — | — | 1 | — | — | 10 | — | 5 | — | — | 5 | — |
| | 29 | 50 | 5 | 10 | 10 | 10 | 10 | 10 | 10 | 10 | — | — | — | — | — | — | — | — | — | — | — | — |
| | 30 | 100 | | 40 | 50 | — | — | — | — | — | — | — | — | — | — | — | — | — | — | — | — | 50 |
| | 31 | — | 100 | 40 | 50 | — | — | — | — | — | — | — | — | — | — | — | — | — | — | — | — | — |
| | 32 | 100 | — | — | 100 | — | — | — | — | — | — | — | 58 | — | — | — | — | — | — | — | — | — |
| | 33 | — | 100 | — | 1 | — | 50 | 10 | 10 | — | — | 1 | 10 | 5 | 5 | 5 | 5 | 5 | 5 | 5 | — | — |
| | 34 | 50 | 10 | — | 5 | 5 | — | — | — | 50 | — | 50 | — | — | — | — | — | — | — | — | — | — |
| | 35 | 50 | 10 | — | — | — | — | — | — | 50 | — | 10 | — | 10 | — | — | — | — | — | — | 5 | 5 |
| | 36 | 50 | 10 | — | — | 10 | — | 10 | — | 10 | — | — | — | — | 5 | — | — | — | — | — | — | — |
| | 37 | 50 | 100 | — | — | — | — | — | — | 100 | 20 | — | — | — | 10 | — | — | 10 | — | 5 | — | 5 |
| | 38 | 50 | — | — | — | — | — | — | — | 100 | — | — | — | — | 100 | — | — | — | — | — | — | — |
| | 39 | 50 | 20 | 10 | 5 | — | 5 | — | 50 | — | 5 | — | — | 5 | — | — | 20 | — | 20 | — | — | — |
| | 40 | 50 | 20 | — | — | — | 100 | 5 | — | — | 10 | — | — | — | — | 10 | — | — | — | — | — | — |
| | 41 | 50 | 50 | — | — | 10 | — | — | 5 | 5 | — | 5 | 5 | 5 | 5 | 5 | 5 | 5 | 5 | 5 | 5 | — |
| | 42 | 30 | 20 | — | — | — | 10 | — | — | — | — | 10 | — | — | — | — | 10 | — | — | — | — | — |
| | 43 | 10 | 50 | — | — | — | 10 | — | — | — | — | — | 50 | — | — | — | — | — | — | — | — | — |
| | 44 | 80 | — | — | — | — | 10 | — | — | — | — | — | 10 | — | — | — | — | — | — | — | — | — |
| | 45 | — | 20 | — | — | 25 | — | 25 | 20 | — | — | — | — | — | 10 | 40 | — | — | — | — | — | — |
| | 46 | 20 | 20 | — | — | — | — | — | — | — | — | 10 | — | — | — | — | 5 | — | 5 | — | — | 30 |
| | 47 | — | — | — | — | — | — | — | — | — | 10 | — | 20 | — | — | — | — | 10 | — | 5 | 5 | — |
| | 48 | — | — | — | — | — | — | — | — | — | — | — | — | 50 | — | — | — | — | — | — | — | — |
| | 49 | — | — | — | — | — | — | — | — | — | — | 50 | — | — | — | — | — | — | — | — | — | — |
| | 50 | — | 20 | — | — | — | — | — | — | — | — | — | — | — | — | 50 | — | — | — | — | — | — |
| | 51 | 50 | 50 | — | — | 100 | — | — | — | — | — | — | — | — | — | — | — | — | — | — | 50 | — |
| | 52 | 10 | 50 | — | — | — | — | — | 100 | — | — | — | — | — | — | — | — | — | 50 | — | — | — |
| | 53 | 5 | 70 | — | — | — | — | 100 | — | — | — | — | — | — | — | — | — | — | 50 | — | — | — |
| | 54 | — | — | — | — | — | — | — | — | — | — | 50 | 50 | — | — | 50 | — | — | — | — | — | — |
| | 55 | — | — | — | — | — | — | — | — | — | — | — | — | 10 | 10 | — | 10 | 10 | — | 10 | 10 | 10 |
| | 56 | 50 | 50 | — | — | — | — | 30 | 20 | 50 | — | — | — | — | — | — | — | — | — | — | — | — |
| | 57 | 50 | 50 | — | — | 1 | — | — | — | — | — | — | — | — | — | — | — | — | — | — | — | — |
| | 58 | 50 | 50 | — | — | — | 1 | — | — | — | — | — | — | — | — | — | — | — | — | — | — | — |
| | 59 | 50 | 50 | — | 1 | — | — | — | 1 | — | — | — | — | — | — | — | — | — | — | — | — | — |
| | 60 | 100 | — | 50 | — | — | — | — | — | — | — | 10 | — | 5 | 5 | 5 | — | 25 | — | — | — | — |
| | 61 | 10 | 10 | 5 | 5 | 5 | 5 | 5 | 5 | 5 | 5 | 5 | 5 | 5 | 5 | 5 | 5 | 5 | 5 | 5 | — | — |
| | 62 | — | 100 | 5 | 5 | 5 | 5 | 5 | 5 | 5 | — | — | — | — | 10 | 10 | — | 10 | — | — | 10 | 10 |
| | 63 | 20 | — | 30 | — | — | 20 | — | 50 | — | 50 | — | — | — | — | — | — | — | — | — | — | — |
| | 64 | — | 20 | — | — | 5 | — | — | 5 | — | — | 40 | — | 10 | — | — | — | — | — | — | — | — |
| | 65 | — | 30 | — | — | — | 10 | 20 | — | — | — | — | 25 | — | — | 25 | — | — | — | — | — | — |
| | 66 | 10 | — | — | 10 | — | — | — | — | — | — | — | — | — | — | — | — | — | — | — | — | — |
| | 67 | 10 | — | — | — | — | — | — | — | — | — | — | — | — | — | 10 | — | — | — | — | — | — |
| | 68 | — | 10 | — | — | — | — | — | — | 10 | — | — | — | — | — | — | — | — | — | — | — | — |
| | 69 | — | 10 | — | — | — | — | — | — | — | — | — | — | — | — | — | — | — | — | — | — | 10 |
| | 70 | 50 | 50 | 50 | — | 10 | 10 | 10 | 10 | 10 | — | — | 20 | — | — | 30 | — | — | — | — | — | — |
| | 71 | 50 | 50 | — | 50 | 10 | 10 | 10 | 10 | 10 | — | — | — | — | — | — | — | 20 | — | — | — | — |
| | 72 | 50 | 50 | — | — | 15 | 50 | 5 | — | — | — | 5 | — | 5 | — | — | — | — | — | 10 | — | — |
| | 73 | 50 | 50 | — | — | — | — | 10 | — | 25 | — | — | — | — | 1 | — | 1 | — | 1 | — | — | — |
| | 74 | 50 | 50 | — | 25 | — | 15 | — | 50 | — | 5 | — | 5 | — | 10 | — | 30 | — | — | — | — | — |
| | 75 | 50 | 50 | 20 | 80 | — | — | — | — | — | — | — | — | — | — | 5 | — | — | 10 | — | 10 | 15 |
| | 76 | 50 | 50 | 80 | — | 20 | — | — | — | — | — | 10 | — | 10 | 10 | — | — | — | — | — | — | — |
| | 77 | 50 | 50 | — | 20 | — | 55 | — | — | 5 | — | — | 50 | — | — | — | — | — | — | — | — | — |
| | 78 | 50 | 50 | — | — | 5 | — | 15 | 50 | — | — | — | — | — | 50 | — | — | — | — | — | — | — |
| | 79 | 50 | 50 | 40 | 40 | — | 20 | — | — | — | — | — | — | — | — | — | — | 50 | — | — | — | — |
| | 80 | 50 | 50 | — | — | 10 | 50 | — | 5 | 5 | — | — | — | — | — | — | — | — | — | 50 | — | — |
| | 81 | 50 | 50 | — | — | — | — | 30 | — | 55 | — | — | — | — | — | 10 | — | — | 10 | — | 10 | — |
| | 82 | 50 | 50 | — | — | — | 50 | 5 | 15 | — | 5 | 5 | 20 | — | — | — | — | — | — | — | — | — |
| | 83 | 50 | 50 | 10 | 10 | 50 | — | — | — | — | — | — | 20 | — | 10 | 5 | — | — | — | — | — | — |
| | 84 | 50 | 50 | 20 | 15 | 45 | 5 | 5 | 5 | 5 | — | — | — | 30 | — | — | 15 | — | — | — | — | — |
| | 85 | 50 | 50 | — | 90 | 10 | — | — | — | — | — | 10 | — | — | 25 | — | — | 5 | — | — | — | — |
| | 86 | 50 | 50 | — | — | — | — | — | — | — | — | — | — | — | — | — | — | — | — | 25 | — | 25 |
| | 87 | 50 | 50 | 20 | 50 | — | — | 15 | 5 | — | — | — | 5 | 5 | 5 | 5 | — | — | 20 | — | 10 | — |
| | 88 | 50 | 50 | — | 5 | — | 45 | — | 5 | 5 | 10 | — | 5 | — | 10 | — | 20 | — | — | — | — | — |
| | 89 | 50 | 50 | — | — | — | — | — | 15 | 15 | — | 10 | — | — | — | 10 | — | 10 | — | 10 | — | — |
| | 90 | 50 | 50 | 5 | 15 | — | 50 | — | — | 10 | 5 | — | 5 | 40 | — | — | — | — | — | — | — | — |
| | 91 | 50 | 50 | — | — | 10 | 30 | — | 50 | — | — | — | — | — | 40 | — | 10 | — | — | — | — | — |
| | 92 | 50 | 50 | — | — | — | — | 50 | — | — | — | — | 5 | 5 | — | — | — | 15 | — | 15 | — | — |
| | 93 | 50 | 50 | 10 | — | 15 | 5 | — | — | — | — | — | — | — | 10 | — | 15 | — | 25 | — | — | — |
| | 94 | 50 | 50 | — | 10 | 15 | 15 | 15 | 15 | 5 | 5 | 5 | 10 | — | — | 10 | — | — | 10 | — | 10 | — |
| | 95 | 50 | 50 | — | — | — | — | — | 45 | — | 15 | 25 | 10 | — | — | — | — | — | — | — | — | — |
| | 96 | 50 | 50 | 40 | — | 30 | — | 30 | — | — | — | — | — | 20 | 25 | — | 5 | — | — | — | — | — |
| | 97 | 50 | 50 | — | — | — | 50 | 15 | — | 5 | — | — | — | — | — | 5 | — | — | 45 | — | — | — |
| | 98 | 50 | 50 | — | 25 | — | — | — | 10 | — | — | — | — | 5 | — | — | — | — | — | 25 | — | 10 |
| | 99 | 50 | 50 | 25 | — | 50 | — | 15 | — | — | — | 5 | — | — | 5 | — | — | 5 | — | 10 | 15 | — |
| | 100 | 50 | 50 | — | 25 | 25 | 25 | 25 | — | — | — | — | 10 | 10 | — | 10 | 10 | — | — | — | — | 10 |
| Conventional | 1 | 40 | 25 | 15 | 100 | — | 10 | 10 | 10 | 10 | — | — | — | — | — | — | — | — | — | — | — | — |
| Example | 2 | 50 | 10 | 50 | 50 | 50 | — | — | — | — | 25 | — | — | — | 20 | — | 70 | — | — | — | — | — |
| | 3 | 10 | 10 | — | 15 | — | 15 | 50 | 50 | — | — | 10 | 25 | — | — | — | — | — | — | — | — | — |

Table 2 below shows results of experimenting a copper bonding wire of the present invention with respect to a low-k wafer recently newly developed and results of experimenting a copper bonding wire manufactured according to the prior art with respect to an existing semiconductor chip and a low-k wafer. As shown in Table 2, a hardness (Hv: Vicker's Hardness Number) of the copper bonding wire was measured by molding and polishing the copper bonding wire at an ambient temperature. A ball shape, metal squeeze out, chip cratering, and a short tail were measured through a ball bonding experiment. For the measured results, ‘∘’ denotes a good state and no generation, ‘Δ’ denotes a normal state and a slight generation, and ‘x’ denotes a poor state and much generation.

TABLE 2

| | | Hard- | | Metal | Chip | |
|---|---|---|---|---|---|---|
| Classi- | | ness | Ball | Squeeze | Cra- | Short |
| fication | | (Hv) | Shape | Out | tering | Tail |
| Present | 1 | 91.2 | ∘ | x | x | x |
| Inven- | 2 | 94.3 | ∘ | x | x | x |
| tion | 3 | 80.1 | ∘ | Δ | Δ | x |
| | 4 | 85.1 | ∘ | x | Δ | x |
| | 5 | 76.2 | ∘ | Δ | Δ | Δ |
| | 6 | 78.8 | ∘ | Δ | Δ | Δ |
| | 7 | 74.7 | ∘ | Δ | Δ | Δ |
| | 8 | 71.4 | ∘ | Δ | Δ | ∘ |
| | 9 | 86.2 | Δ | Δ | Δ | x |
| | 10 | 77.6 | ∘ | Δ | Δ | Δ |
| | 11 | 95.5 | ∘ | x | x | x |
| | 12 | 98.5 | ∘ | x | x | x |
| | 13 | 81.5 | ∘ | Δ | Δ | x |
| | 14 | 73.4 | ∘ | Δ | x | Δ |
| | 15 | 79.9 | ∘ | Δ | Δ | x |
| | 16 | 82.1 | ∘ | Δ | Δ | x |
| | 17 | 84.2 | ∘ | Δ | Δ | Δ |
| | 18 | 86.1 | ∘ | Δ | Δ | Δ |
| | 19 | 89.3 | Δ | Δ | Δ | x |
| | 20 | 83.6 | ∘ | Δ | Δ | x |
| | 21 | 95.4 | ∘ | Δ | Δ | x |
| | 22 | 94.4 | Δ | x | x | x |
| | 23 | 89.3 | Δ | Δ | ∘ | Δ |
| | 24 | 71.4 | ∘ | ∘ | ∘ | ∘ |
| | 25 | 69.4 | ∘ | ∘ | ∘ | ∘ |
| | 26 | 73.8 | Δ | Δ | Δ | Δ |
| | 27 | 72.8 | Δ | Δ | Δ | Δ |
| | 28 | 68.5 | ∘ | ∘ | ∘ | ∘ |
| | 29 | 66.2 | ∘ | ∘ | ∘ | ∘ |
| | 30 | 67.6 | ∘ | ∘ | ∘ | ∘ |
| | 31 | 69.7 | ∘ | ∘ | ∘ | ∘ |
| | 32 | 99.4 | Δ | x | x | x |
| | 33 | 62.5 | ∘ | ∘ | ∘ | ∘ |
| | 34 | 61.9 | ∘ | ∘ | ∘ | ∘ |
| | 35 | 62.8 | ∘ | ∘ | ∘ | ∘ |
| | 36 | 63.2 | ∘ | ∘ | ∘ | ∘ |
| | 37 | 71.9 | Δ | Δ | Δ | Δ |
| | 38 | 69.9 | ∘ | Δ | Δ | Δ |
| | 39 | 64.0 | ∘ | ∘ | ∘ | ∘ |
| | 40 | 64.8 | ∘ | ∘ | ∘ | ∘ |
| | 41 | 61.9 | ∘ | ∘ | ∘ | ∘ |
| | 42 | 62.5 | ∘ | ∘ | ∘ | ∘ |
| | 43 | 61.4 | ∘ | ∘ | ∘ | ∘ |
| | 44 | 60.9 | ∘ | ∘ | ∘ | ∘ |
| | 45 | 59.7 | ∘ | ∘ | ∘ | ∘ |
| | 46 | 62.0 | ∘ | ∘ | ∘ | ∘ |
| | 47 | 70.8 | Δ | ∘ | ∘ | Δ |
| | 48 | 67.2 | Δ | ∘ | ∘ | Δ |
| | 49 | 69.0 | Δ | ∘ | ∘ | Δ |
| | 50 | 64.1 | ∘ | ∘ | ∘ | ∘ |
| | 51 | 64.8 | ∘ | Δ | ∘ | ∘ |
| | 52 | 65.0 | ∘ | Δ | ∘ | ∘ |
| | 53 | 65.8 | ∘ | Δ | ∘ | ∘ |
| | 54 | 79.2 | Δ | x | x | x |
| | 55 | 81.2 | Δ | Δ | Δ | x |
| | 56 | 62.4 | ∘ | Δ | ∘ | ∘ |
| | 57 | 62.5 | ∘ | ∘ | ∘ | ∘ |
| | 58 | 62.9 | ∘ | ∘ | ∘ | ∘ |
| | 59 | 61.2 | ∘ | ∘ | ∘ | ∘ |
| | 60 | 63.8 | ∘ | ∘ | ∘ | ∘ |
| | 61 | 64.2 | ∘ | ∘ | ∘ | ∘ |
| | 62 | 63.5 | ∘ | ∘ | ∘ | ∘ |
| | 63 | 63.4 | ∘ | ∘ | ∘ | ∘ |
| | 64 | 69.0 | ∘ | ∘ | ∘ | ∘ |
| | 65 | 67.4 | ∘ | ∘ | ∘ | ∘ |
| | 66 | 68.2 | ∘ | ∘ | ∘ | Δ |
| | 67 | 70.1 | ∘ | Δ | ∘ | Δ |
| | 68 | 71.1 | ∘ | ∘ | ∘ | Δ |
| | 69 | 70.9 | ∘ | Δ | ∘ | Δ |
| | 70 | 71.5 | ∘ | Δ | ∘ | ∘ |
| | 71 | 72.4 | ∘ | Δ | ∘ | ∘ |
| | 72 | 68.4 | ∘ | ∘ | ∘ | ∘ |
| | 73 | 62.9 | ∘ | ∘ | ∘ | ∘ |
| | 74 | 64.5 | ∘ | ∘ | ∘ | ∘ |
| | 75 | 69.8 | ∘ | Δ | ∘ | ∘ |
| | 76 | 72.4 | ∘ | Δ | ∘ | ∘ |
| | 77 | 74.6 | ∘ | ∘ | ∘ | ∘ |
| | 78 | 71.0 | ∘ | ∘ | ∘ | ∘ |
| | 79 | 62.1 | ∘ | Δ | ∘ | ∘ |
| | 80 | 60.2 | ∘ | ∘ | ∘ | ∘ |
| | 81 | 61.1 | ∘ | ∘ | ∘ | ∘ |
| | 82 | 61.6 | ∘ | ∘ | ∘ | ∘ |
| | 83 | 62.4 | ∘ | ∘ | ∘ | ∘ |
| | 84 | 67.8 | ∘ | Δ | ∘ | ∘ |
| | 85 | 64.0 | ∘ | Δ | ∘ | ∘ |
| | 86 | 74.2 | ∘ | x | Δ | ∘ |
| | 87 | 60.9 | ∘ | ∘ | ∘ | ∘ |
| | 88 | 60.1 | ∘ | ∘ | ∘ | ∘ |
| | 89 | 63.1 | ∘ | ∘ | ∘ | ∘ |
| | 90 | 62.4 | ∘ | ∘ | ∘ | ∘ |
| | 91 | 62.8 | ∘ | ∘ | ∘ | ∘ |
| | 92 | 61.1 | ∘ | ∘ | ∘ | ∘ |
| | 93 | 61.3 | ∘ | ∘ | ∘ | ∘ |
| | 94 | 61.0 | ∘ | ∘ | ∘ | ∘ |
| | 95 | 62.1 | ∘ | ∘ | ∘ | ∘ |
| | 96 | 61.9 | ∘ | Δ | ∘ | ∘ |
| | 97 | 61.4 | ∘ | ∘ | ∘ | ∘ |
| | 98 | 59.9 | ∘ | ∘ | ∘ | ∘ |
| | 99 | 63.1 | ∘ | ∘ | ∘ | Δ |
| | 100 | 62.8 | ∘ | Δ | ∘ | Δ |

| | | | Hard- | | Metal | Chip | |
|---|---|---|---|---|---|---|---|
| Classi- | | | ness | Ball | Squeeze | Cra- | Short |
| fication | | | (Hv) | Shape | Out | tering | Tail |
| Conven- | Existing | 1 | 85.1 | ∘ | ∘ | ∘ | Δ |
| tional | Semi- | 2 | 92.3 | Δ | Δ | ∘ | Δ |
| | conductor | | | | | | |
| Example | Chip | 3 | 78.6 | ∘ | ∘ | ∘ | Δ |
| | Low-k | 1 | 85.1 | ∘ | Δ | x | Δ |
| | Semi- | 2 | 92.3 | Δ | x | x | Δ |
| | conductor | | | | | | |
| | Chip | 3 | 78.6 | ∘ | Δ | x | Δ |

As shown in Table 2, in a case where the conventional copper bonding wire is used in the existing semiconductor chip, metal squeeze out and chip cratering are good. However, in a case where the conventional copper bonding wire is used in the low-k semiconductor chip, metal squeeze out and chip cratering are remarkably poor. However, the short tail unrelated to the semiconductor chip occurs regardless of variations in the hardness.

In a case where at least one of P and Nb is added within a range between 20 wt ppm and 100 wt ppm according to the experiment in which the copper bonding wire of the present invention is applied to a low-k semiconductor chip, minute amounts of inevitable impurities O and S as deoxidization and desulfurization components contained in a high purity copper during forming of a ball of the copper bonding wire are removed and a reaction between O around the high purity copper and the high purity copper is prevented. Thus, the ball shape is good, and occurrences of metal squeeze out and chip cratering are reduced. However, the short tail continuously occurs.

In a case where at least one of Zr, Sn, Be, Nd, Sc, Ga, Fr, and Ra within a range between 20 wt ppm and 100 wt ppm is added to a high purity copper including at least one of P and Nb within a range between 20 wt ppm and 100 wt ppm as in the embodiment of the present invention, as shown in Table 2, an ambient temperature tensile strength of the copper bonding wire is lowered, and a softness of the copper bonding wire is increased. Thus, metal squeeze out is reduced during ball bonding. Also, the occurrence of the short tail is reduced. In a case where a total content exceeds 100 wt ppm, an amount of a non-reactive element remaining not evaporating during forming of the ball is increased. Thus, the hardness of the ball is increased. As a result, the occurrences of metal squeeze out and chip cratering are increased as shown in Table 2.

In a case where at least one of Cs, Lu, Ta, Re, Os, Ir, Po, At, Pr, Pm, Sm, and Gd within a range between 1 wt ppm and 50 wt ppm is added to a high purity copper including at least one of P and Nb within a range between 20 wt ppm and 100 wt ppm as in the another embodiment of the present invention, the hardness of the copper bonding wire is lowered. Thus, the hardness of the ball is also lowered. As a result, the occurrences of chip cratering and the short tail are reduced.

In a case where at least one of Zr, Sn, Be, Nd, Sc, Ga, Fr, and Ra within a range between 1 wt ppm and 100 wt ppm and at least one of Cs, Lu, Ta, Re, Os, Ir, Po, At, Pr, Pm, Sm, and Gd within a range between 1 wt ppm and 50 wt ppm is added to a high purity copper including at least one of P and Nb within a range between 20 wt ppm and 100 wt ppm, the hardness of the copper bonding wire is lowered, and an ambient temperature elongation ratio of the copper bonding wire is increased. Thus, the occurrence of the short tail is reduced. Also, an oxide layer is prevented from being formed on a surface of the ball during forming of the ball, and S remaining in the copper bonding wire is evaporated to maximize the softness of the. ball. As a result, the occurrences of metal squeeze out and chip cratering are effectively reduced as shown in Table 2.

As described above, in a copper bonding wire for semiconductor packaging according to the present invention, the bonding wire can be as hard as a gold bonding wire. A ball can have a good shape and an appropriate hardness. Thus, occurrences of metal squeeze out and chip cratering can be reduced. An occurrence of a short tail in which a bonding wire is bonded to a lead finger in a lead frame and easily broken down can be reduced. Thus, the copper bonding wire can be used as a loop wire in a semiconductor package instead of an existing gold bonding wire.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A copper bonding wire formed of a high purity copper of 99.999% or more comprising at least one of P and Nb within a range between 20 wt ppm and 100 wt ppm and at least one of Zr, Sn, Be, Nd, Sc, Ga, Fr, and Ra within a range between 1 wt ppm and 100 wt ppm,
wherein a total content of the added elements is restricted within a range between 20 wt ppm and 200 wt ppm, and a residual amount of the copper bonding wire is a high purity copper of 99.98% or more.

2. A copper bonding wire formed of a high purity copper of 99.999% or more comprising at least one of P and Nb within a range between 20 wt ppm and 100 wt ppm and at least one of Cs, Lu, Ta, Re, Os, Ir, Po, At, Pr, Pm, Sm, and Gd within a range 1 wt ppm and 50 wt ppm,
wherein a total content of the added elements is restricted within a range between 20 wt ppm and 150 wt ppm, and a residual amount of the copper bonding wire is a high purity copper of 99.98% or more.

3. A copper bonding wire formed of a high purity copper of 99.999% or more comprising at least one of P and Nb within a range between 20 wt ppm and 100 wt ppm, at least one of Zr, Sn, Be, Nd, Sc, Ga, Fr, and Ra within a range between 1 wt ppm and 100 wt ppm, and at least one of Cs, Lu, Ta, Re, Os, Ir, Po, At, Pr, Pm, Sm, and Gd within a range between 1 wt ppm and 50 wt ppm,
wherein a total content of the added elements is restricted within a range between 20 wt ppm and 250 wt ppm, and a residual amount of the copper bonding wire is a high purity copper of 99.98% or more.
